(19) United States
(12) Patent Application Publication
(10) Pub. No.: US 2026/0298505 A1
(43) Pub. Date: Oct. 1, 2026

(54) VORTEX TUBE ASSEMBLY, CHARGER, AND COOLING SYSTEM

(71) Applicants: Hyundai Motor Company, Seoul (KR); Kia Corporation, Seoul (KR)

(72) Inventors: Woo Hyung LEE, hWASEONG-SI (KR); Su Hwan Cho, Hwaseong-Si (KR)

(73) Assignees: Hyundai Motor Company, Seoul (KR); Kia Corporation, Seoul (KR)

(21) Appl. No.: 19/327,754

(22) Filed: Sep. 12, 2025

(30) Foreign Application Priority Data
Mar. 31, 2025 (KR) 10-2025-0041176

(51) Int. Cl. F25B 9/04; H05K 7/20

(52) U.S. Cl. CPC F25B 9/04; H05K 7/20909

(57) ABSTRACT

A vortex tube assembly includes a vertex tube and a pipe including one end portion connected to the vortex tube and transporting cooled air discharged from the vortex tube, wherein the pipe includes air holes disposed at regular intervals to discharge the cooled air therethrough.

### CROSS-REFERENCE TO RELATED APPLICATIONS

The present application claims benefit of priority to Korean Patent Application No. 10-2025-0041176 filed on Mar. 31, 2025 in the Korean Intellectual Property Office, the disclosure of which is incorporated herein by reference in its entirety.

### TECHNICAL FIELD

The present disclosure relates to a vortex tube assembly, a charger, and a cooling system.

It is to be noted that the contents described in the present section simply provide background information on the present disclosure and do not constitute related art.

Power modules are core elements of electric vehicle chargers and serve to convert alternating current (AC) electricity into direct current (DC) electricity, while minimizing power loss by utilizing power semiconductors as switches within chargers. Power modules are core components of rapid chargers directly supplying direct current to electric vehicles at a high speed without having to go through an onboard charger in vehicles.

Power modules generate heat during operation thereof, and as charging capacity increases, high-temperature heat occurs due to high voltage and high current. Therefore, it is very important to manage heat occurring in power modules to improve charging stability of rapid chargers.

To solve the heat generation problem, an air-cooled or water-cooled power module has been generally used. The air-cooled type does not require a separate chiller, so it is easy to install and has an economical advantage, but cooling performance thereof is low. The water-cooled type requires space for chiller installation and requires maintenance.

### SUMMARY

An aspect of the present disclosure is to provide a vortex tube assembly, a charger, and a cooling system, lowering the temperature of the air exhausted from a power module of a charger, enabling stable driving of the power module, and reducing the size of equipment for lowering the temperature inside the charger, enabling development of a compact charger, and at the same time, energy savings.

According to an aspect of the present disclosure, a vortex tube assembly may include: a vortex tube; and a pipe having a first end portion fastened to the vortex tube and transporting cooled air discharged from the vortex tube, wherein the pipe may include air holes disposed at regular intervals to discharge the cooled air therethrough.

The pipe may be disposed in a form surrounding an object.

The air holes may be formed in a direction toward the object.

The second end portion of the pipe may be blocked.

At least two objects may be disposed, the at least two objects may be configured in a stacked manner, and the pipe may be configured in a zig-zag shape to surround at least one object of each layer.

The pipe may include: a straight first pipe including at least one air hole among the air holes for discharging cooled air in the direction toward the object; a connecting pipe connected to the first pipe for changing a direction connected to the first pipe; and a straight second pipe connected to the connecting pipe for changing a direction and including at least one air hole among the air holes discharging cooled air in the direction toward the object, wherein the straight first pipe, the connecting pipe, and the straight second pipe are repeatedly connected.

The pipe disposed between the layers may include at least one air hole among the air holes formed in both directions.

According to another aspect of the present disclosure, a charger includes: an internal casing including a power module on one side, the power module including a power conversion device converting alternating current into direct current and an intake fan intaking cooled air to reduce heat occurring during a conversion process; and a vortex tube assembly discharging cooled air through the intake fan.

The vortex tube assembly may include: a vortex tube; and a pipe including a first end portion connected to the vortex tube and transporting cooled air discharged from the vortex tube, wherein the pipe may include air holes disposed at regular intervals to discharge the cooled air therethrough.

The second end portion of the pipe may be blocked.

At least two the power modules may be disposed, the at least two or more of the power modules may be configured in a stacked manner, and the pipe may be configured in a zig-zag shape to surround an intake portion including at least one intake fan disposed in at least one power module of each layer.

The pipe may include: a straight first pipe including at least one air hole among the air holes for discharging cooled air in the direction of the intake portion; a connecting pipe connected to the first pipe for changing a direction connected to the first pipe; and a straight second pipe connected to the connecting pipe for changing a direction and including at least one air hole among the air holes discharging cooled air in the direction of the intake portion, wherein the straight first pipe, the connecting pipe, and the straight second pipe are repeatedly connected.

The pipe disposed between the layers may include at least one air hole among the air holes formed in both directions.

The vortex tube may be disposed at a rear of the charger.

According to another aspect of the present disclosure, a cooling system includes: an air compressor compressing air to generate high-pressure air; an oil filter purifying oil used in the air compressor; an air dryer removing moisture from the high-pressure air; and a charger configured to be cooled using the high-pressure air from which the moisture has been removed, wherein the charger includes: an internal casing including a power module on one side, the power module including a power conversion device converting alternating current into direct current and an intake fan intaking cooled air to reduce heat occurring during a conversion process; and a vortex tube assembly discharging cooled air through the intake fan.

### BRIEF DESCRIPTION OF DRAWINGS

The and other aspects, features, and advantages of the present disclosure will be more clearly understood from the following detailed description, taken in conjunction with the accompanying drawings, in which:

FIG. 1 is a diagram illustrating an operating principle of a general vortex tube;

FIG. 2 is a diagram illustrating a vortex tube assembly according to an exemplary embodiment of the present disclosure;

FIG. 3 is a diagram illustrating the exterior of a charger including a vortex tube assembly according to an exemplary embodiment of the present disclosure;

FIG. 4 is a diagram illustrating an internal casing of a charger according to an exemplary embodiment of the present disclosure; and

FIG. 5 is a diagram illustrating a cooling system according to an exemplary embodiment of the present disclosure.

### DETAILED DESCRIPTION

Hereinafter, embodiments of the present disclosure are described with reference to the accompanying drawings. The following description is provided to aid in the comprehensive understanding of methods, devices, and/or systems included in the particularities. However, the following description is merely exemplary and is not provided to limit the present disclosure.

In the following description of the present disclosure, a detailed description of known functions and configurations incorporated herein will be omitted when it would render the subject matter of the present disclosure unclear. The terms used in the present specification are defined based on functions used in an exemplary embodiment of the present disclosure, and may be changed according to the intent or conventionally used methods of clients, operators, and users. Accordingly, definitions of the terms should be understood based on the entire description of the present specification. Terms used in the following description are merely provided to describe embodiments of the present disclosure and are not intended to be limiting of the inventive concept. As used herein, the singular forms “a,” “an” and “the” are intended to include the plural forms as well, unless the context clearly indicates otherwise. It will be further understood that the terms “includes” or “has” when used in the present specification, specify the presence of stated features, integers, steps, operations, elements, or a portion or combination thereof, but do not preclude the presence or addition of one or more other features, integers, steps, operations, elements, or a portion or combination thereof.

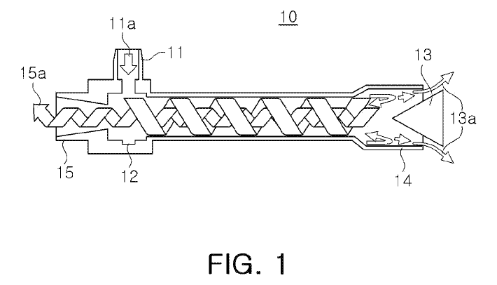

FIG. 1 is a diagram illustrating an operating principle of a typical vortex tube.

Vortex tubes, cooling devices simultaneously generating flow of cold air and hot air without any mechanical drive units, being inexpensive, being highly reliable, and requiring no maintenance, have been used in high-temperature industrial sites, such as welding and manufacturing processes for molten metal.

As illustrated in FIG. 1, compressed air 11a is supplied to a vortex tube 10 through a compressed air inlet 11, and the compressed air 11a is sprayed perpendicularly to a longitudinal direction of the vortex tube 10, while contacting with the internal side of a vortex rotation chamber 12. The air sprayed in the present manner forms a vortex like a whirlwind and moves to the end portion of the vortex tube 10 along an internal wall of the vortex tube 10.

Here, when a valve 13 attached to the end portion of the vortex tube 10 is slightly opened, a portion of high-temperature air 13a is discharged externally through a high-temperature air outlet 14, and the remaining air which is not discharged changes in direction and flows back, while forming a small vortex along the center portion of the vortex tube 10.

The air that flows back in the present manner is cooled and becomes low-temperature air 15a, and the low-temperature air 15a is discharged externally through a low-temperature air outlet 15.

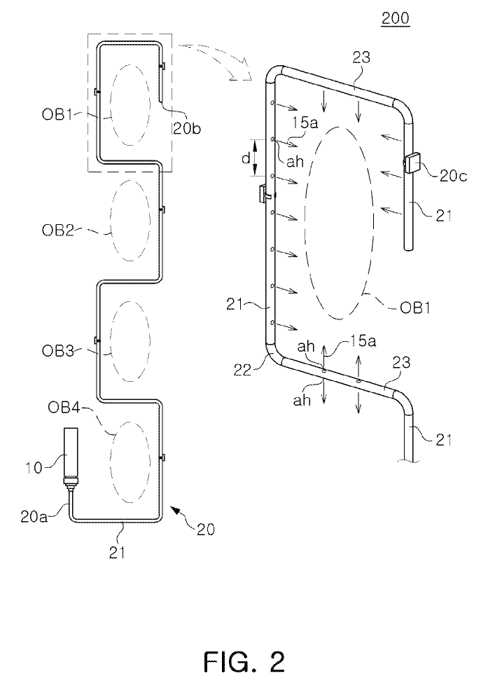

FIG. 2 is a diagram illustrating a vortex tube assembly according to an exemplary embodiment of the present disclosure.

As illustrated in FIGS. 1 and 2, a vortex tube assembly 200 according to an exemplary embodiment of the present disclosure includes the vortex tube 10 and a pipe 20 including one end portion 20a connected to the vortex tube 10 and transporting the low-temperature air 15a discharged from the vortex tube 10, and air holes ah may be formed at regular intervals d in the pipe 20 to discharge the low-temperature air 15a. The other end portion 20b of the pipe 20 may be blocked. The pipe 20 may be formed of a material for preventing heat loss, for example, copper.

The pipe 20 may be disposed in a form surrounding an object, and the air holes ah may be formed in the direction of the object.

According to an exemplary embodiment of the present disclosure, at least two or more objects OB1, OB2, OB3, and OB4 are included. The at least two or more objects OB1, OB2, OB3, and OB4 may be configured in a stacked manner, and in the instant case, the pipe 20 may be configured in a zig-zag shape as illustrated in FIG. 2 to surround the objects of the respective layers.

The pipe 20 may be configured in a zig-zag shape in which a straight first pipe 21 including at least one air hole among the air holes ah for discharging the low-temperature air 15a toward the object, a connecting pipe 22 for changing a direction connected to the first pipe 21, and a straight second pipe 23 including at least one air hole among the air holes ah for discharging the low-temperature air 15a toward the object are repeatedly connected.

Meanwhile, at least one air hole among the air holes ah may be formed in both directions in the pipe 23 disposed between the layers. For example, in FIG. 2, the air holes ah may be formed on both sides of the pipe 23 to discharge the low-temperature air 15a toward the object OB1 and the object OB2.

The pipe 20 may be mounted on an internal casing 320 by a bracket 20c fixed to a side wall 321 of the internal casing 320 in which a plurality of power modules are accommodated.

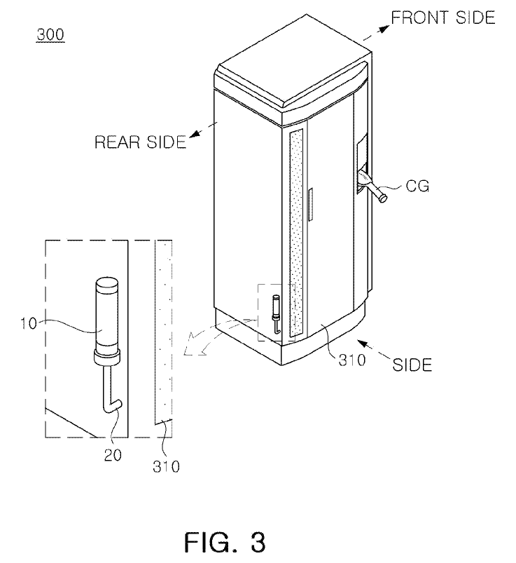

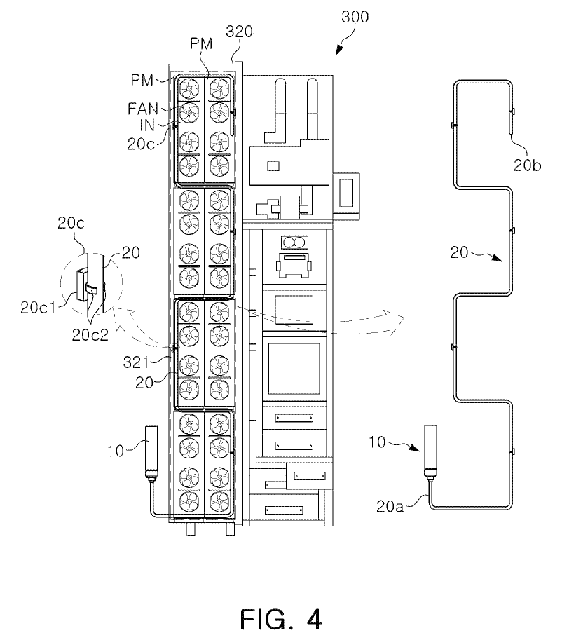

Meanwhile, FIG. 3 is a diagram illustrating the exterior of a charger including a vortex tube assembly according to an exemplary embodiment of the present disclosure, and FIG. 4 is a diagram illustrating an internal casing of the charger according to an exemplary embodiment of the present disclosure.

As illustrated in FIG. 3, a charging gun CG is mounted on a charger 300, and an electric vehicle may be charged using the charging gun CG.

Furthermore, as illustrated in FIG. 3, the vortex tube 10 of the vortex tube assembly 200 may be disposed on the rear side of the charger 300, and by providing the vortex tube 10 on the rear side of the charger 300, the vortex tube 10 is not visible from the front side of the charger 300, enhancing the aesthetics. A control panel may be disposed on the front side of the charger 300.

Furthermore, a side case 310 may be disposed on the side of the charger 300, and when the side case 310 is opened, the internal casing 320, such as that illustrated in FIG. 4, may be revealed.

Referring to FIGS. 2 and 4, a plurality of power modules PM may be accommodated in the internal casing 320. The power module PM may include a power conversion device converting alternating current (AC) electricity into direct current (DC) electricity and an intake fan FAN intaking the low-temperature air 15a to cool down heat occurring during a conversion process. At least two power modules PM may be disposed, and the at least two power modules PM may be stacked. FIG. 4 illustrates a total of eight power modules in which two power modules are stacked in four layers. Furthermore, each power module PM may include the intake fan FAN.

Furthermore, the charger 300 may include the vortex tube assembly 10 and 20 for discharging the low-temperature air 15a to the intake fan FAN.

Furthermore, as described above, the vortex tube assembly 10 and 20 may include the vortex tube 10 and the pipe 20 including one end portion 20a connected to the vortex tube 10 and transporting the low-temperature air 15a discharged from the vortex tube 10, and the air holes ah may be formed at regular intervals d in the pipe 20 to discharge the low-temperature air 15a. Furthermore, the other end portion 20b of the pipe 20 may be blocked.

The pipe 20 may be fixed to the side wall 321 of the internal casing 320 by the bracket 20c. That is, a plurality of brackets 20c may be disposed on the side wall 321 of the internal casing 320 in which the power module is accommodated, and each of the brackets 20c may include a fixing member 20c1 fixed to the side wall 321 of the internal casing 320 by screw coupling or the like and a pair of extension members 20c2 protruding from the fixing member 20c1. As the pipe is introduced into the space between the pair of extension members 20c2, the pipe 20 may be disposed on the internal casing 320.

Furthermore, the pipe 20 may be configured in a zig-zag shape to surround an intake portion IN including at least one intake fan FAN disposed in at least one power module PM of each layer.

The pipe may be configured in a zig-zag shape in which the straight first pipe 21 including at least one air hole among the air holes ah for discharging the low-temperature air 15a in the direction of the intake portion IN, the connecting pipe 22 for changing a direction connected to the first pipe 21, and the straight second pipe 23 including at least one air hole among the air holes for discharging the low-temperature air 15a toward the intake portion IN are repeatedly connected.

Furthermore, at least one air hole among the air holes ah may be formed in both directions in the pipe 23 disposed between layers.

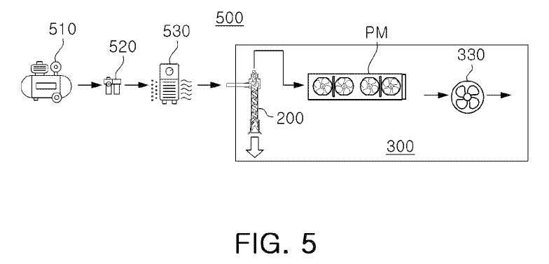

Finally, FIG. 5 is a diagram illustrating a cooling system according to an exemplary embodiment of the present disclosure.

As illustrated in FIG. 5, a cooling system 500 according to an exemplary embodiment of the present disclosure may include an air compressor 510 compressing air to generate high-pressure air, an oil filter 520 purifying oil used in the air compressor 510, an air dryer 530 removing moisture from the high-pressure air, and the charger 300 cooled using the high-pressure air from which moisture has been removed. As described above, the charger 300 may include the vortex tube assembly 200 and the power module PM. Reference numeral 330 denotes an exhaust fan disposed in the charger 300.

As described above, according to an exemplary embodiment of the present disclosure, the pipe for transporting low-temperature air discharged from the vortex tube is connected to one end portion of the vortex tube, and air holes are formed at regular intervals in the pipe to discharge low-temperature air to the intake portion of the power module to lower the temperature of air discharged from the power module of the charger, enabling stable operation of the power module and reducing the size of equipment for lowering the temperature inside the charger, enabling development of a compact charger.

Furthermore, according to an exemplary embodiment of the present disclosure, by utilizing the low-temperature temperature of the vortex tube together for cooling, energy saving may be expected compared to a case in which cooling is performed only with the existing intake fan and exhaust fan.

While the present disclosure has been illustrated and described with reference to various exemplary embodiments thereof, a person skilled in the art will understand that the invention is not limited to the disclosed exemplary embodiments but may be variously modified within the scope of the present disclosure. Therefore, the scope of the present disclosure should not be limited to the above-described embodiments but should be determined by all changes or modifications derived from the scope of the appended claims and equivalents of the following claims.

What is claimed is:

1. A vortex tube assembly comprising:
a vortex tube; and
a pipe including a first end portion connected to the vortex tube and transporting cooled air discharged from the vortex tube,
wherein the pipe includes air holes disposed at regular intervals to discharge the cooled air therethrough.

2. The vortex tube assembly of claim 1, wherein the pipe is disposed to surround an object.

3. The vortex tube assembly of claim 2, wherein the air holes are disposed in a direction toward the object.

4. The vortex tube assembly of claim 1, wherein a second end portion of the pipe is blocked.

5. The vortex tube assembly of claim 2,
wherein at least two objects are disposed,
wherein the at least two objects are configured in a stacked manner, and
wherein the pipe is configured in a zig-zag shape to surround at least one object of each layer.

6. The vortex tube assembly of claim 5,
wherein the pipe includes:
a straight first pipe including at least one air hole among the air holes for discharging the cooled air in a direction toward the object;
a connecting pipe connected to the first pipe for changing a direction connected to the first pipe; and
a straight second pipe connected to the connecting pipe for changing a direction and including at least one air hole among the air holes discharging the cooled air in the direction toward the object,
wherein the straight first pipe, the connecting pipe, and the straight second pipe are repeatedly connected.

7. The vortex tube assembly of claim 6, wherein the pipe disposed between the layers includes at least one air hole among the air holes formed in both directions.

8. A charger comprising:
an internal casing including a power module on one side, the power module including a power conversion device converting alternating current into direct current and an intake fan intaking cooled air to reduce heat occurring during a conversion process; and
a vortex tube assembly discharging the cooled air through the intake fan.

9. The charger of claim 8,
wherein the vortex tube assembly includes:
a vortex tube; and
a pipe including a first end portion connected to the vortex tube and transporting the cooled air discharged from the vortex tube,
wherein the pipe includes air holes disposed at regular intervals to discharge the cooled air therethrough.

10. The charger of claim 9, wherein a second end portion of the pipe is blocked.

11. The charger of claim 9,
wherein at least two the power modules are disposed,
wherein the at least two or more of the power modules are configured in a stacked manner, and
wherein the pipe is configured in a zig-zag shape to surround an intake portion including at least one intake fan disposed in at least one power module of each layer.

12. The charger of claim 11,
wherein the pipe includes:
a straight first pipe including at least one air hole among the air holes for discharging the cooled air in a direction of the intake portion;
a connecting pipe connected to the first pipe for changing a direction connected to the first pipe; and
a straight second pipe connected to the connecting pipe for changing a direction and including at least one air hole among the air holes discharging the cooled air in the direction of the intake portion, and
wherein the straight first pipe, the connecting pipe, and the straight second pipe are repeatedly connected.

13. The charger of claim 12, wherein the pipe disposed between the layers includes at least one air hole among the air holes formed in both directions.

14. The charger of claim 9, wherein the vortex tube is disposed at a rear of the charger.

15. A cooling system comprising:
an air compressor compressing air to generate pressured air;
an oil filter purifying oil used in the air compressor;
an air dryer removing moisture from the pressured air; and
a charger configured to be cooled using the pressured air from which the moisture has been removed,
wherein the charger includes:
an internal casing including a power module on one side, the power module including a power conversion device converting alternating current into direct current and an intake fan intaking cooled air to reduce heat occurring during a conversion process; and
a vortex tube assembly discharging the cooled air through the intake fan.

16. The cooling system of claim 15, wherein the vortex tube assembly includes:
a vortex tube; and
a pipe including a first end portion connected to the vortex tube and transporting the cooled air discharged from the vortex tube,
wherein the pipe includes air holes disposed at regular intervals to discharge the cooled air therethrough.

17. The cooling system of claim 16, wherein the pipe is disposed to surround an object.

18. The cooling system of claim 17, wherein the air holes are disposed in a direction toward the object.
